(19) United States
(12) Patent Application Publication
(10) Pub. No.: US 2008/0144300 A1
(43) Pub. Date: Jun. 19, 2008

(54) Circuit board and manufacturing method thereof

(75) Inventor: Kiyotake Nohara, Nagano (JP)

Correspondence Address: DYKEMA GOSSETT PLLC, FRANKLIN SQUARE, THIRD FLOOR WEST, 1300 I STREET, NW, WASHINGTON, DC, 20005, US

(73) Assignee: SHINKO CO., LTD.

(21) Appl. No.: 12/000,632

(22) Filed: Dec. 14, 2007

(30) Foreign Application Priority Data
Dec. 15, 2006 (JP) 2006-339004

(51) Int. Cl. H01K 3/10; H05K 7/00

(52) U.S. Cl. 361/783; 29/850

(57) ABSTRACT

The present invention provides a circuit board in which generation of a white-blushed mark which is partially produced at a blank portion having no wiring pattern at a rim of an opening portion is suppressed when forming the opening portion by punching, and a manufacturing method thereof in the circuit board in which a portion where a wiring pattern is dense and the blank portion having no wiring pattern are present at a rim of a central part of the circuit board.

There is provided a circuit board having an opening portion formed at the center of the circuit board by punching, the circuit board having a structure where a dummy electrode pattern connected with a rim of the opening portion is provided besides a wiring pattern which is connected with the opening portion at the rim of the opening portion and used for wire bonding. It is preferable to provide the dummy electrode pattern having a size satisfying S/d≧0.33, where S is an area of the dummy electrode pattern and d is a sum total of lengths of sides where the dummy electrode pattern is connected with the rim of the opening portion.

### BACKGROUND OF THE INVENTION

1. Field of the Invention

The present invention relates to a circuit board on which a semiconductor device is mounted, and more particularly to a circuit board which has an opening portion at the center thereof to connect a semiconductor device with the circuit board through a bonding wire, and a manufacturing method thereof.

2. Description of the Related Art

In general, when implementing a semiconductor device in an electronic device, a technique of mounting the semiconductor device on a circuit board in advance and assembling the circuit board having the semiconductor device mounted thereon in the electronic device is adopted to increase an efficiency of an implementing operation. At this time, an electrode of the semiconductor device is connected with a terminal on the circuit board through a bonding wire. In order to reduce a length of the bonding wire, an opening portion is formed at the center of the circuit board and an electrode of the small semiconductor device is connected with a terminal portion of a circuit wiring line around the opening portion through the bonding wire.

In such a circuit board 101 which is assembled as a semiconductor device and has an opening portion 3 at the center thereof as shown in FIG. 11, an etching resist layer is provided on a copper layer by using an insulative base material 17, e.g., a glass base material copper-clad lamination to form a predetermined etching resist pattern, a copper layer portion exposed from this etching resist pattern is molten and removed, and then the etching resist pattern is removed, thereby forming a predetermined wiring pattern 15 made of the copper layer. Subsequently, a solder resist layer is provided to form a predetermined solder resist pattern, Ni/Au plating is performed with respect to a wiring pattern exposed from this solder resist pattern, and then the opening portion 3 is formed at the center of the circuit board by a router bit.

In order to avoid occurrence of burrs and removal of the wiring pattern when forming the opening portion by the router bit, there is a method of forming a circuit wiring pattern at a position where the opening portion is formed in such a manner that this pattern is inclined at a sharp angle, which is preferably a sharp angle of 15 degrees or more, with respect to a surface perpendicular to a moving direction of the router bit and a width of the wiring pattern becomes 90 μm or more (see, e.g., Patent Document 1).

Further, in this circuit board 101 having the opening portion at the center thereof, the wiring pattern 15 is a wiring pattern which is close to an electrode 12 of a semiconductor device 11 in order to reduce a length of a bonding wire 13 which connects the electrode 12 of the semiconductor device 11 with the wiring pattern 15 of the circuit board 101, and a portion 4 where a wiring pattern 2 is dense and a blank portion 5 having no wiring pattern 2 are present at a rim of the opening portion at the center of the circuit board 101 as shown in FIG. 12.

In recent years, as compared with formation of the opening portion by the router bit, formation of the opening portion by punching with high productivity has been demanded. However, when the opening portion is formed by punching, a white-blushed mark 6 which has a size of approximately 0.3 mm and looks white is newly partially produced at a part shown in FIG. 13 in the blank portion having no wiring pattern at the rim of the opening portion by an influence of punching.

Since this white-blushed mark 6 can be observed from a surface of the circuit board, an inconvenience may possibly occur in, e.g., image recognition at a subsequent step like wire bonding, and occurrence of the white-blushed mark must be eliminated or greatly reduced, or observing this region must be disabled.

Patent Document 1: Japanese Patent Application Laid-open print No. 2000-315751

It is an object of the present invention to provide a circuit board and a manufacturing method thereof which can avoid occurrence of a white-blushed mark which is partially produced at a blank portion having no wiring pattern at a rim of an opening portion when the opening portion is formed by punching in the circuit board in which a portion where the wiring pattern is dense and the blank portion having no wiring pattern are present at the rim of the opening portion at the center of the circuit board.

### SUMMARY OF THE INVENTION

To achieve this object, according to a first aspect of the present invention, there is provided a circuit board having an opening portion formed in a substrate thereof, wherein a dummy pattern connected with a rim of an arc part of the opening portion is provided besides a wiring pattern connected with a rim of the opening portion.

Further, in the circuit board, the dummy pattern is formed of branch patterns connected with the rim of the arc part of the opening portion on a periodic base, and it is formed of a plurality of branch patterns connected with the rim of the arc part of the opening portion on a periodic base and a coupling portion connecting one end of each of the branch patterns.

Furthermore, a gap between the plurality of branch patterns as the dummy pattern is 0.3 mm or less, and the coupling portion connecting one end of each of the branch patterns is formed in a range which is 0.3 mm or less from the arc part of the opening portion.

When according to a second aspect of the present invention the circuit board is configured as explained above, even if a portion where the wiring pattern is dense and a blank portion having no wiring pattern are present at the rim of the opening portion at the center of the circuit board, presence of the dummy electrode pattern in the blank portion enables suppressing a white-blushed mark produced at the rim of the opening portion due to punching.

Moreover, according to a third aspect of the present invention even if a white-blushed mark is generated, it is hardly seen when it is placed in the range of 0.2 mm or less from the opening portion, and erroneous recognition by an optical device at a subsequent step does not occur.

The circuit board can be manufactured by forming a wiring pattern and a dummy pattern coupled with each other in a range serving as an opening portion of a substrate, then forming the opening portion by punching and, at the same time, electrically disconnecting the wiring pattern and the dummy pattern from each other. According to this method, the wiring pattern and the dummy pattern can be simultaneously formed and their film thicknesses can be increased by electroplating which is performed to these patterns at the same time, thereby greatly simplifying the process.

Additionally, when an area of the dummy pattern is reduced as much as possible, an amount of plating which is essentially unnecessary can be decreased.

According to the present invention, it is possible to provide the circuit board whose productivity can be greatly improved by forming the opening portion by punching as compared with that when forming the opening portion by a router bit and in which generation of a white-blushed mark due to punching can be suppressed by providing the dummy electrode pattern.

As a result, an obstacle when recognizing an image can be eliminated, and hence an effect of greatly improving efficiency at an implementation step can be demonstrated.

### BRIEF DESCRIPTION OF THE DRAWINGS

FIG. 1 is a view showing a cross-sectional structure at the center of a circuit board according to the present invention;

FIG. 2 is a plan view showing the center of the circuit board depicted in FIG. 1;

FIG. 3 is a plan view showing an example of a dummy electrode pattern;

FIG. 4 is a plan view showing another example of the dummy electrode pattern;

FIG. 5 is a plan view showing still another example of the dummy electrode pattern;

FIG. 6 is a plan view showing yet another example of the dummy electrode pattern;

FIG. 7 is a plan view showing a further example of the dummy electrode pattern;

FIG. 8 is a view for explaining an area of the dummy electrode pattern and a joint length with respect to an opening portion;

FIG. 9 is a view showing a relationship between a ratio of an area of the dummy electrode pattern and a joint length with respect to the opening portion and a removal occurrence rate;

FIG. 10 is a view showing a manufacturing process of the dummy electrode pattern;

FIG. 11 is a view showing a cross-sectional structure of the circuit board;

FIG. 12 is a view showing an arrangement of circuit wiring lines on the circuit board; and

FIG. 13 is a view showing a white-blushed mark of the circuit board.

### DETAILED DESCRIPTION OF THE PREFERRED EMBODIMENTS

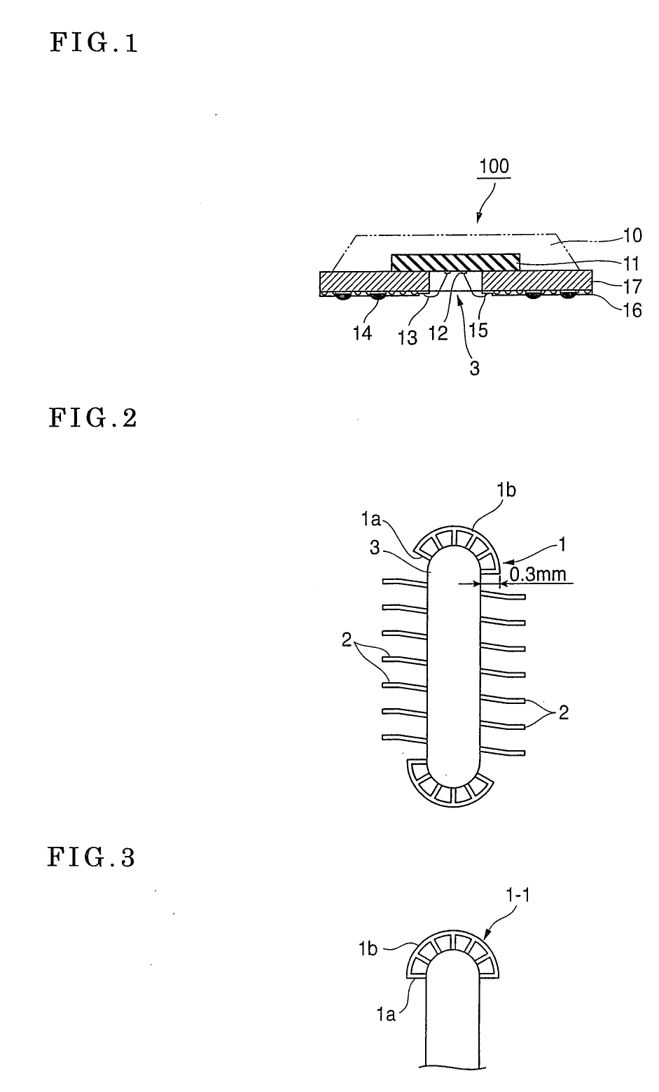

FIG. 1 is a view showing a cross-sectional structure of a circuit board according to the present invention, and FIG. 2 is a plan view of the center of the circuit board depicted in FIG. 1.

As shown in FIG. 1, in a circuit board 100 according to the present invention, a semiconductor device 11 is mounted on one surface of an insulative base material 17 having an opening portion 3 formed at the center, and a wiring pattern and connection terminals 14 for the outside which are continuous with the wiring pattern are provided on the other surface of the insulative base material 17. Electrodes 12 are provided on a surface of the semiconductor device 11 on the insulative base material side, and each electrode 12 is connected with a bonding portion at a distal end of the wiring pattern 15 through a bonding wire 13 in the opening portion 3. Further, the semiconductor device 11 is covered with and protected by a sealing resin 10, and the other surface of the insulative base material 17 is protected by a solder resist 16 except end portions of the connection terminals 14.

In the plane, as shown in FIG. 2, a plurality of (14 in FIG. 2) wiring patterns 2 and a dummy pattern 1 are formed at a rim of the opening portion 3 at the center of the insulative base material. Each wiring pattern 2 is connected with the connection terminal (not shown) for the outside. The dummy pattern 1 is constituted of several blocks (two upper and lower blocks in FIG. 2). Here, the wiring patterns 2 are formed in accordance with the number of the electrodes of the semiconductor device, and the dummy pattern 1 is arranged and formed to fill a region having no wiring pattern formed therein at rims of upper and lower arc parts of the opening portion 3.

In the example depicted in FIG. 2, the dummy pattern 1 is formed of six branch patterns 1a which are in contact with the rim of the opening portion 3 and an arc pattern 1b connecting ends of these six branch patterns 1a, and connecting the ends of the branch patterns 1a by the arc pattern 1b enables obtaining stronger bonding strength.

The most outer profile of the arc pattern 1b is formed in the range of 0.3 mm or less from the opening portion. That is because forming the dummy pattern near the opening portion alone can avoid generation of a white-blushed mark since production of the white-blushed mark due to punching is limited to a position near the opening portion.

In the circuit board according to the present invention, even if the white-blushed mark is generated due to punching the opening portion, a position of the white-blushed mark is restricted to the range of 0.2 mm or less from the rim of the opening portion 3. Therefore, erroneous recognition by an optical device at a subsequent step does not occur.

FIGS. 3 to 7 show other examples of the shape of the dummy pattern.

In the circuit board having an oval opening portion formed therein, each arc part serves as a blank portion having no wiring pattern, and hence a wheel-shaped dummy electrode pattern is formed at this arc part.

FIG. 3 shows an example in which a blank portion having no wiring pattern is provided at each arc part of the opening portion 3 and hence a wheel-shaped dummy pattern 1-1 is formed at this portion. This dummy pattern 1-1 is constituted by connecting ends of seven branch patterns 1a by an arc pattern 1b.

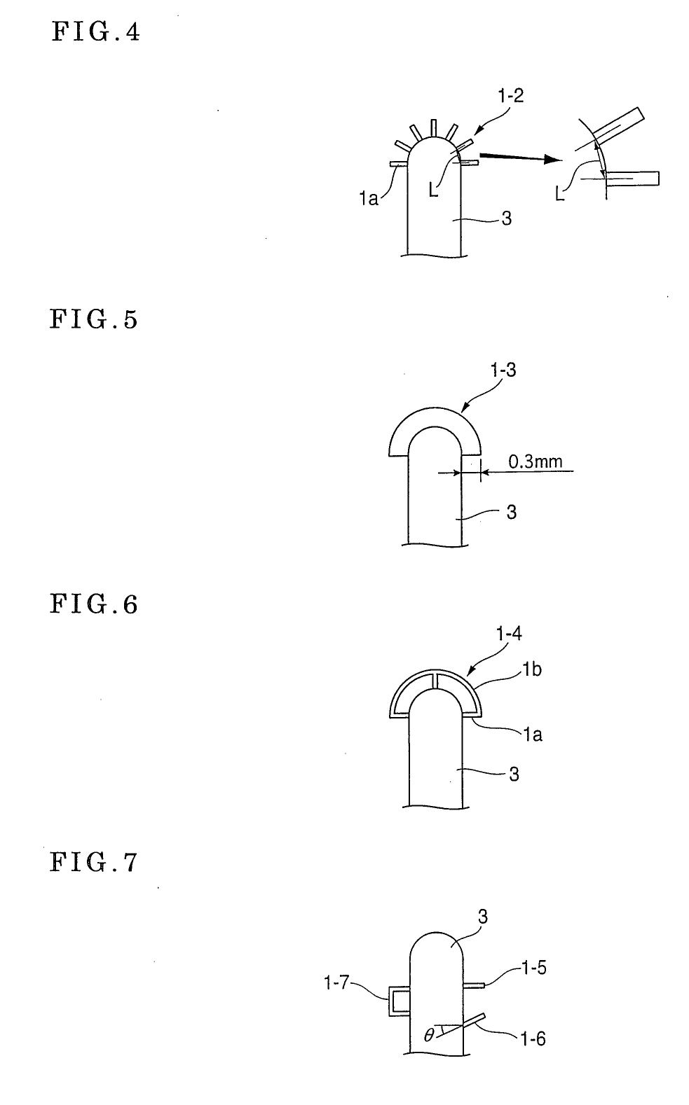

FIG. 4 is an example in which a dummy pattern 1-2 is formed of seven branch patterns 1a.

When forming dummy patterns by being brought into contact with the opening portion at a plurality of contact points, it is preferable to form each gap L between the dummy patterns (branch patterns in this example) adjacent to each other to 0.3 mm or less.

This structure suppresses generation of a white-blushed mark.

FIG. 5 shows an example where a single solid dummy pattern 1-3 which is in contact with the arc part of the opening portion 3 is formed.

An adhesion force is large since a ratio of an opening portion contact area with respect to a pattern area is increased, and hence the dummy pattern which is hardly removed at the time of punching can be provided.

FIG. 6 shows an example where a dummy pattern 1-4 is formed of three branch patterns 1a and an arc pattern 1b connecting ends of these branch patterns 1a.

The robust dummy pattern which is hardly removed at the time of punching can be provided.

Since a shape of the blank portion is limited by the wiring pattern at each straight part of the opening portion, a dummy electrode pattern vertical to the opening portion or a dummy electrode pattern having an angle with respect to the same is formed.

FIG. 7 shows an example where blank portions having no wiring portion are provided at straight parts of the opening portion 3 and hence dummy patterns are formed at these portions.

Since a shape of each blank portion is restricted by the wiring pattern at each straight part of the opening portion, when forming a dummy electrode pattern on each straight part at the rim of the opening portion, a branch-shaped dummy pattern 1-5 vertical to the straight part at the rim of the opening portion can be formed, a branch-shaped dummy pattern 1-6 having a fixed angle θ can be formed at the straight part of the opening portion 3, or a dummy pattern 1-7 connecting respective ends of a plurality of (two in the drawing) branch-shaped dummy patterns vertical to the rim can be formed. In case of the dummy pattern having the branch-like simple shape, since the dummy pattern may be removed at the time of punching, the branch-shaped dummy pattern 1-6 having a fixed angle at the straight part is more preferable than the branch pattern vertical to the opening portion. The angle θ may be approximately 15 to 45 degrees.

In any dummy pattern, it is preferable to provide the dummy pattern at a position in the range of 0.3 mm or less from the edge of the opening portion 3. Furthermore, when forming a plurality of branch-shaped dummy patterns, a gap between the respective dummy patterns must be set to 0.3 mm or less. In regard to this structure, uniformly dispersing and arranging both the patterns without the blank portion having no wiring pattern.

In the circuit board according to the present invention, assuming that S is an area of the dummy pattern and d is a sum total of lengths of sides where the dummy pattern is connected with the opening portion, providing a size achieving S/d≧0.33 enables assuring sufficient bonding strength.

The area S of the dummy electrode pattern and the length d of the sides where the dummy pattern is connected with the opening portion will now be explained hereinafter in detail.

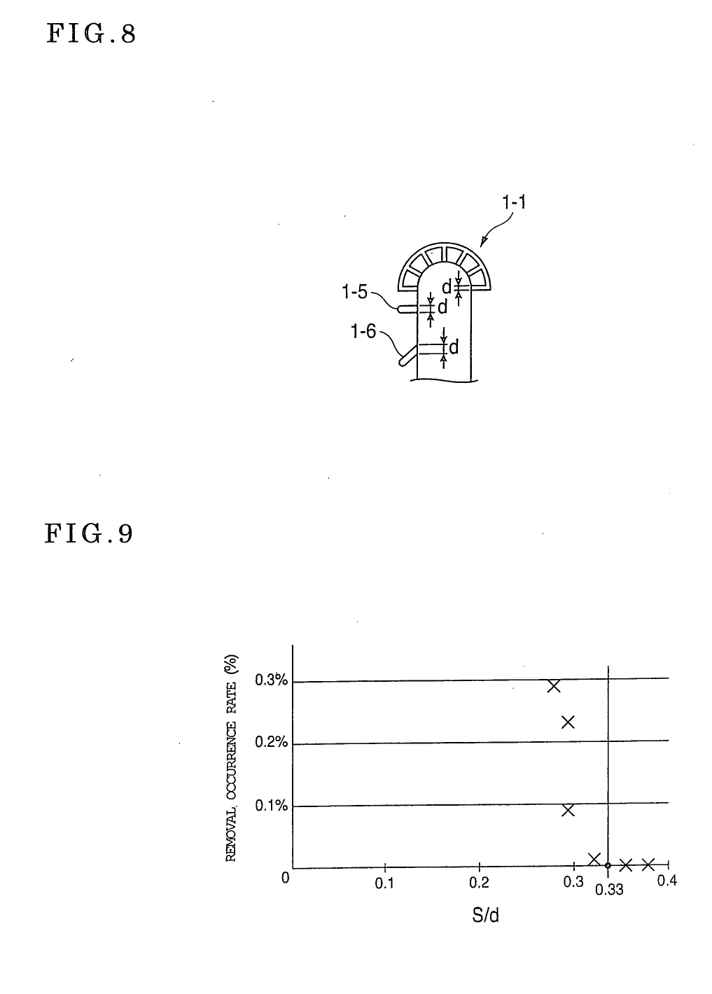

FIG. 8 is a plan view showing a dummy electrode pattern rim portion of the circuit board according to the present invention. As shown in FIG. 8, when dummy electrode patterns are provided at the arc part of the opening portion and the straight part of the opening portion in the circuit board according to the present invention, it is preferable to provide each dummy electrode pattern having a size satisfying the condition S/d≧0.33 in accordance with each independent block.

Here, the area S of the dummy electrode pattern means a sum total of areas of the dummy electrode patterns, and it is an area obtained by adding a sum total of areas of the six branch patterns 1a and an area of the single arc pattern 1b in the example depicted in FIG. 2.

Moreover, the length d of the sides where the dummy electrode pattern is connected with the opening portion means a length of the sides where the dummy electrode pattern is connected with the opening portion literally.

The case depicted in FIG. 8 is an example where the dummy electrode patterns are provided at the arc part of the opening portion and the straight part of the opening portion, and it is preferable to provide each of a wheel-shaped dummy electrode pattern 1-1 and branch patterns 1-5 and 1-6 as a dummy electrode pattern having a size satisfying the condition S/d≧0.33.

Each of the simple-shaped dummy electrode patterns 1-5 to 1-7 depicted in FIG. 7 also has a size satisfying S/d≧0.33, where S is an area of the dummy electrode pattern and d is a sum total of lengths of sides where the dummy electrode pattern is connected with the opening portion.

This structure is provided in order to assure sufficient bonding strength for each dummy electrode pattern.

In accordance with an arrangement of the wiring patterns formed at the rim of the opening portion, the wheel-shaped dummy electrode pattern and the branch-shaped dummy electrode pattern are combined to form the dummy electrode at the blank portion so that the electrode patterns are uniformly dispersed and arranged.

Since the dummy pattern having a simple shape is apt to be removed at the time of punching, it has been revealed that the pattern having an angle with respect to the rim of the opening portion is hardly removed as compared with the pattern vertical to the rim of the opening portion. However, since the dummy pattern having an angle cannot be always formed because of shapes of the peripheral wiring patterns, a size of a dummy pattern which is a branch pattern, has high bonding strength, and is hardly removed was examined.

That is, dummy electrode patterns were formed while changing the area S of the dummy electrode pattern and the sum total d of lengths of sides where the dummy electrode pattern is connected with the opening portion in many ways, punching was effected, and occurrence rates of removal of the dummy electrode patterns were checked. FIG. 9 shows a result. As depicted in the drawing, it can be understood that removal of the dummy electrode pattern does not occur when a value of S/d is 0.33 or more.

A manufacturing method of the circuit board according to the present invention will now be explained.

A circuit board requiring a dummy electrode pattern is a circuit board in which an opening portion is formed at the center thereof by punching, and this corresponds to a case where a portion where a wiring pattern is dense and a blank portion having not wiring pattern are present at a rim of the opening portion. That is because presence of the blank portion leads to readily generating a white-blushed mark at the blank portion when performing punching of the opening portion.

In the circuit board according to the present invention, a general glass base material copper-clad lamination is used as an insulative base material, and a wiring pattern is formed simultaneously with a dummy pattern based on, e.g., a semi-additive method, a subtractive method, or a full-additive method.

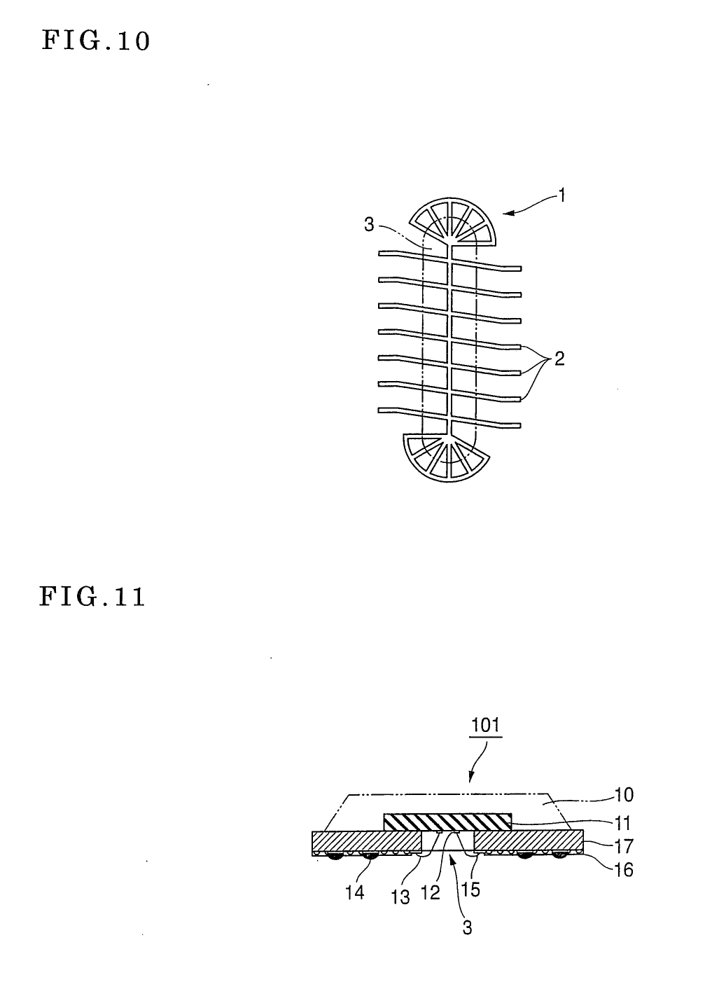

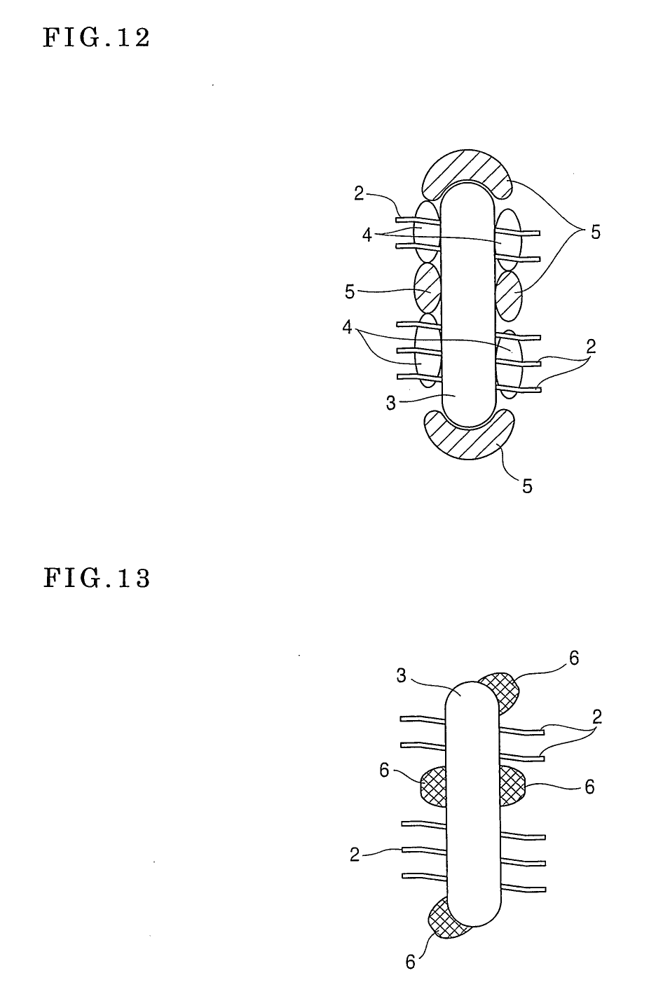

First, as shown in FIG. 10, a dummy electrode pattern 1 is formed at a blank portion of an opening portion 3 indicated by a broken line except wiring patterns 2. The dummy pattern 1 is formed as a pattern which is electrically integrally connected with the wiring patterns 2 in a region serving as the opening portion 3 simultaneously with formation of the wiring patterns 2. The electrically connected patterns are provided in order to perform the same plating as that of the wiring patterns to the dummy pattern at a step of effecting Ni/Au plating to the wiring patterns.

At this time, the dummy pattern having a size satisfying S/d≧0.33 is formed, where S is an area of the dummy pattern and d is a sum total of lengths of sides where the dummy pattern is connected with the opening portion.

Exposure/development is performed with respect to a surface of a copper layer on a surface of the base material by using a photomask having a predetermined shape to etch the copper layer, thereby forming the desired wiring patterns and dummy pattern.

Subsequently, a solder resist is applied, then Ni plating based on electroplating is performed to the surface of the copper layer as the wiring patterns and the dummy pattern emerged after exposure/development/post curing using a predetermined mask, and Au plating is further carried out to improve electrical conductivity.

At last, punching is performed by using a die having a predetermined shape to form the opening portion and, at the same time, the dummy pattern is separated from the wiring patterns, thereby obtaining a wiring board.

### EXAMPLES

A glass fabric base material epoxy copper-clad lamination with a thickness of 0.18 mm which has a copper layer with a thickness of 0.02 mm on one surface thereof was used to laminate a photoresist on the copper layer, then exposure/development was performed by using a photo mask to etch the copper layer, thereby forming wiring patterns and dummy patterns having various shapes and size.

Subsequently, a solder resist was applied, a predetermined mask was used to effect exposure/development, and then 10-μm Ni plating and 0.7-μm Au plating based on electroplating were performed to a surface of the copper layer as the emerged dummy pattern and wiring patterns. Additionally, punching was effected by using a die to form an opening portion.

It is to be noted that the dummy pattern and the wiring patterns are formed as patterns electrically integrally connected at a part serving as the opening portion as shown in FIG. 10 and then punching is performed so that electrical conduction is interrupted as shown in FIG. 2.

The dummy pattern was selected from such patterns as depicted in FIGS. 3 to 6 and formed at each arc part of the opening portion. Further, when the opening portion has straight parts, the dummy pattern was selected from the patterns depicted in FIGS. 3 to 6 and formed at each arc part of the opening portion, and one or more dummy patterns were selected from those shown in FIG. 7 in the straight part, combined and formed.

FIG. 3 shows a dummy pattern constituted of an arc shape having a line width of 0.1 mm at a position 0.1 mm away from a rim of the opening portion and branch-shaped patterns with a width of 0.1 mm having seven extraction lines connected with the arc shape. The seven branch-shaped dummy patterns were set to form an angle of 30 degrees therebetween. A gap between the respective patterns in the opening portion is approximately 0.2 mm.

Furthermore, as the dummy electrode pattern shown in FIG. 4, a dummy pattern was formed of seven branch-shaped patterns each having a width of 0.1 mm and a length of 0.35 mm. The respective patterns were set to form an angle of 30 degrees therebetween. A gap between the respective patterns in the opening portion is approximately 0.2 mm.

It is to be noted that removal of the pattern occurred at the time of punching when the length was 0.1 mm or 0.2 mm in the same shape.

In FIG. 5, a semicircular solid-shaped dummy pattern having a width of 0.3 mm was formed at the arc rim of the opening portion.

It is to be noted that removal often occurred after punching when the width was 0.1 mm, 0.15 mm, or 0.2 mm in the same shape.

In FIG. 6, three branch-shaped patterns were arranged at intervals of 90 degrees and respective ends thereof were connected with each other through an arc pattern. A line width of each pattern is 0.1 mm, and a length of the branch-shaped pattern is 0.3 mm.

FIG. 7 shows an example of dummy patterns formed at straight parts of the opening portion.

As the dummy pattern 1-5, a pattern having a width of 0.1 mm and a length of 0.35 mm was formed at a right angle with respect to the rim of the opening portion.

As the dummy pattern 1-6, a pattern having a width of 0.1 mm and a length of 0.4 mm was formed at an angle of 30 degrees at the rim of the opening portion.

As the dummy electrode pattern 1-7, a U-shaped pattern having a width of 0.1 mm and each outer peripheral side of 0.3 mm was formed.

Combinations of patterns shown in Table 1 were used to form dummy electrode patterns, and each punched circuit board was observed. Presence/absence of removal the dummy electrode patterns and presence/absence and a size of each white-blushed mark were observed. Table 2 shows results.

TABLE 1

| | | | | | | | | Dummy | | |
|---|---|---|---|---|---|---|---|---|---|---|
| | | | | | | | | electrode | | |
| | Opening arc part | | | Opening straight part | | | | total | | |
| | | | Contact | | | | Contact | | Contact | |
| | | Area | length | | | Area | length | Area S | length | |
| No. | Shape | (mm²) | (mm) | Shape | Quantity | (mm²) | (mm) | (mm²) | d (mm) | S/d |
| Example 1 | FIG. 3 | 0.2722 | 0.6711 | | | | | 0.2722 | 0.6711 | 0.4056 |
| Example 2 | FIG. 3 | 0.2692 | 0.4814 | | | | | 0.2692 | 0.4814 | 0.5593 |
| Example 3 | FIG. 5 | 0.6332 | 1.6137 | | | | | 0.6332 | 1.6137 | 0.3924 |
| Example 4 | FIG. 6 | 0.2283 | 0.2833 | | | | | 0.2283 | 0.2833 | 0.8059 |
| Example 5 | FIG. 4 | 0.1662 | 0.4812 | | | | | 0.1662 | 0.4812 | 0.3454 |
| Example 6 | | | | FIG. 7 | 1 | 0.0377 | 0.1109 | 0.0377 | 0.1109 | 0.3399 |
| | | | | 1-5 | | | | | | |
| Example 7 | | | | FIG. 7 | 1 | 0.0311 | 0.1100 | 0.0311 | 0.1100 | 0.2822 |
| | | | | 1-6(30°) | | | | | | |
| Example 8 | | | | FIG. 7 | 1 | 0.0253 | 0.1119 | 0.0253 | 0.1119 | 0.2261 |
| | | | | 1-6(45°) | | | | | | |
| Example 9 | | | | FIG. 7 | 1 | 0.0361 | 0.1038 | 0.0361 | 0.1038 | 0.3479 |
| | | | | 1-5 | | | | | | |
| Example 10 | | | | FIG. 7 | 1 | 0.0380 | 0.1116 | 0.0380 | 0.1116 | 0.3405 |
| | | | | 1-5 | | | | | | |
| Example 11 | | | | FIG. 7 | 1 | 0.0399 | 0.1154 | 0.0399 | 0.1154 | 0.3458 |
| | | | | 1-5 | | | | | | |
| Example 12 | | | | FIG. 7 | 1 | 0.0395 | 0.1097 | 0.0395 | 0.1097 | 0.3601 |
| | | | | 1-5 | | | | | | |
| Comparative | FIG. 5 | 0.3881 | 1.6137 | | | | | 0.3881 | 1.16137 | 0.2405 |
| Example 1 | | | | | | | | | | |
| Comparative | FIG. 4 | 0.0813 | 0.4775 | | | | | 0.0813 | 0.4775 | 0.1703 |
| Example 2 | | | | | | | | | | |
| Comparative | | | | FIG. 7 | 1 | 0.0278 | 0.1074 | 0.0278 | 0.1074 | 0.2588 |
| Example 3 | | | | 1-5 | | | | | | |
| Comparative | | | | FIG. 7 | 1 | 0.0350 | 0.1178 | 0.0350 | 0.1178 | 0.2973 |
| Example 4 | | | | 1-5 | | | | | | |
| Comparative | | | | FIG. 7 | 1 | 0.0275 | 0.1184 | 0.0275 | 0.1184 | 0.2323 |
| Example 5 | | | | 1-6(30°) | | | | | | |
| Comparative | | | | FIG. 7 | 1 | 0.0200 | 0.1345 | 0.0200 | 0.1345 | 0.1487 |
| Example 6 | | | | 1-6(45°) | | | | | | |

TABLE 2

| | | White-blushed mark | | |
|---|---|---|---|---|
| | Presence/absence of | Presence/ | Wiring | Size |
| No. | removal in punching | absence | gap (mm) | (mm) |
| Example 1 | Absence | Presence | 0.1391 | 0.0443 |
| Example 2 | Absence | Presence | 0.2572 | 0.0448 |
| Example 3 | Absence | Absence | | |
| Example 4 | Absence | Presence | 0.6120 | 0.0639 |
| Example 5 | Absence | Presence | 0.2576 | 0.1165 |
| Example 6 | Absence | Presence | 0.1023 | 0.0514 |
| Example 7 | Absence | Presence | 0.0988 | 0.0652 |
| Example 8 | Absence | Presence | 0.1569 | 0.0778 |
| Example 9 | Absence | Presence | 0.3064 | 0.1451 |
| Example 10 | Absence | Presence | 0.2999 | 0.1450 |
| Example 11 | Absence | Presence | 0.2983 | 0.1265 |
| Example 12 | Absence | Presence | 0.3017 | 0.1359 |
| Comparative | Presence | Absence | | |
| Example 1 | | | | |
| Comparative | Presence | Presence | 0.2579 | 0.1419 |
| Example 2 | | | | |
| Comparative | Presence | Presence | 0.0983 | 0.1458 |
| Example 3 | | | | |
| Comparative | Presence | Presence | 0.3152 | 0.1359 |
| Example 4 | | | | |
| Comparative | Presence | Presence | 0.1215 | 0.0882 |
| Example 5 | | | | |
| Comparative | Presence | Presence | 0.1801 | 0.1645 |
| Example 6 | | | | |

Based on the results depicted in Tables 1 and 2, according to the present invention, providing the dummy electrode patterns enables suppressing generation of a white-blushed mark, thus eliminating an obstacle when recognizing an image. Further, forming the opening portion based on punching can improve an efficiency at the implantation step.

1. A circuit board having an opening portion formed in a substrate thereof, wherein a dummy electrode pattern connected with a rim of an arc part of the opening portion is provided besides a wiring pattern connected with a rim of the opening portion.

2. The circuit board according to claim 1, wherein the dummy pattern is formed of branch patterns connected with the rim of the arc part of the opening portion on a periodic base.

3. The circuit board according to claim 1, wherein the dummy pattern is formed of a plurality of branch patterns connected with the rim of the arc part of the opening portion on a periodic base and a coupling portion connecting one end of each of the branch patterns.

4. The circuit board according to claim 1, wherein a gap between the plurality of branch patterns as the dummy pattern is 0.3 mm or less.

5. The circuit board according to claim 3, wherein the coupling portion connecting one end of each of the branch patterns is formed in a range which is 0.3 mm or less from the arc part of the opening portion.

6. A circuit board having an opening portion formed in a substrate thereof by punching, wherein a white-blushed mark is generated in a range of 0.2 mm or less from an arc part of the opening portion.

7. A manufacturing method of a circuit board, wherein a wiring pattern and a dummy pattern coupled with each other in a range serving as an opening portion of a substrate are formed, then the opening portion is formed by punching and, at the same time, the wiring pattern and the dummy pattern are electrically disconnected from each other.
